(19) United States
(12) Patent Application Publication
(10) Pub. No.: US 2003/0189960 A1
(43) Pub. Date: Oct. 9, 2003

(54) Coherent light source and production method thereof

(76) Inventors: Yasuo Kitaoka, Osaka (JP); Kiminori Mizuuchi, Osaka (JP); Kazuhisa Yamamoto, Osaka (JP); Shinichi Takigawa, Osaka (JP)

Correspondence Address: MERCHANT & GOULD PC, P.O. BOX 2903, MINNEAPOLIS, MN, 55402-0903, US

(21) Appl. No.: 10/381,405

(22) PCT Filed: Jul. 29, 2002
(86) PCT No.: PCT/JP02/07705

(30) Foreign Application Priority Data
Jul. 30, 2001 (JP) 2001-229067

(51) Int. Cl. H01S 3/04; H01S 5/00

(52) U.S. Cl. 372/36; 372/43

(57) ABSTRACT

The emission angle and emission position of coherent light source are controlled with high precision. A wavelength-variable DBR semiconductor laser (1) and an optical waveguide-type QPM-SHG device (2) are mounted on a submount (7), and the submount (7) is fixed inside a package (11), thus obtaining a coherent light source. Reference lines (A) and (B) serving as reference markers when fixing the submount (7) are formed on a submount fixing face of the package (11).

### TECHNICAL FIELD

The present invention relates to coherent light sources that include a semiconductor laser and an optical waveguide device and are fixed inside a package, as well as methods for manufacturing the same.

### BACKGROUND ART

Coherent light sources using a semiconductor laser and a quasi phase matching (referred to as “QPM” in the following) optical waveguide-type second harmonic generation (referred to as “SHG” in the following”) device (referred to as “optical waveguide-type QPM-SHG device” in the following) have drawn attention as a small short-wavelength light sources (see Yamamoto et al., Optics Letters, Vol. 16, No. 15, 1156 (1991)).

FIG. 12 diagrammatically shows the configuration of an SHG blue light source using an optical waveguide-type QPM-SHG device.

As shown in FIG. 12, in this SHG blue light source, a wavelength-variable distributed Bragg reflection (referred to as “DBR” in the following) semiconductor laser 54 having a DBR region is used as the semiconductor laser. The wavelength-variable DBR semiconductor laser 54 is a 0.85 μm-band 100 mW-class AlGaAs wavelength-variable DBR semiconductor laser, and is provided with an active layer region 56, a phase control region 57 and a DBR region 58. The oscillation wavelength can be changed continuously by simultaneously changing the current injected into the phase control region 57 and the DBR region 58.

The optical waveguide-type QPM-SHG device 55 used as the wavelength converting element is made of an optical waveguide 60 and periodic polarization inversion region 61 formed on a 0.5 mm thick X-cut MgO-doped LiNbO₃ substrate 59. The optical waveguide 60 is produced by proton exchange in pyrophosphoric acid. Moreover, the periodic polarization inversion regions 61 are produced by forming comb-shaped electrodes on the X-cut MgO-doped LiNbO₃ substrate 59 and applying an electric field.

In the SHG blue light source with the above configuration, the wavelength-variable DBR semiconductor laser 54 and the optical waveguide-type QPM-SHG device 55 are mounted on a Si submount 62, such that 60 mW of laser light are coupled to the optical waveguide 60 for 100 mW of the laser output. By controlling the current injected into the phase control region 57 and the DBR region 58 of the wavelength-variable DBR semiconductor laser 54, the oscillation wavelength is fixed within the phase-matching wavelength tolerance of the optical waveguide-type QPM-SHG device (wavelength converting device) 55. Using this SHG blue light source, about 10 mW of blue light of 425 nm wavelength is obtained, but the transverse mode of the obtained blue light is the TE00 mode and has diffraction limited focusing properties, and also the noise level is low with a relative intensity noise (RIN) of less than −140 dB/Hz.

Ordinarily, in semiconductor lasers, return light noise leading to an increase of intensity noise occurs due to light that returns after being reflected from the outside, such as an optical disk. In SHG blue light sources, however, the blue light obtained from the wavelength conversion is guided to the outside, so that return light noise does not occur. On the other hand, the noise due to return light increases in the semiconductor laser serving as the fundamental wave, so that it is necessary to reduce the return light into the semiconductor laser. That is to say, it is necessary to reduce the return light from the optical waveguide-type QPM-SHG device.

In order to reduce the return light from the optical waveguide-type QPM-SHG device, a method of obliquely cutting the emission-side end face of the device has been suggested (JP 2000-171653A). By cutting the emission-side end face obliquely at 6°, the amount of the return light can be made several hundreds times smaller, and as a result, a stable output operation and a reduction of noise can be realized.

In SHG blue light sources made of a semiconductor laser and an optical waveguide-type QPM-SHG device that has been obliquely cut in this manner, the beam obtained from the emission-side end face is refracted into an oblique direction in accordance with Snell's law. If the SHG blue light source is used for a optical disk device or the like, then it has to be controlled such that the beam is emitted perpendicularly to the emission-side end face of the package, that is, the emission window. Ordinarily, the emission-side end face is provided with an emission window (of transparent glass or the like), and when light is emitted in an oblique direction with respect to the emission window, then astigmatism occurs when the light is focused. That is to say, the emission angle and the emission position need to be controlled with high precision. Then, when the emission angle and the emission position are controlled with high precision in this manner, then the optical transmission efficiency can be made large.

### DISCLOSURE OF INVENTION

With the foregoing in mind, it is an object of the present invention to provide a coherent light source, in which the emission angle and the emission position are controlled with high precision, as well as a method for manufacturing the same.

In order to achieve this object, in a first configuration of a coherent light source in accordance with the present invention, at least a semiconductor laser and an optical waveguide device are mounted on a submount, the submount is fixed inside a package, and a reference marker serving as a reference when fixing the submount is formed on a submount fixing face of the package. With this first configuration of a coherent light source, a coherent light source in which the emission angle and the emission position are controlled with high precision can be realized by forming the reference marker with high precision and fixing the submount taking the reference marker formed on the submount fixing face of the package as a reference.

In this first configuration of a coherent light source according to the present invention, it is preferable that the submount is fixed in such a manner that an emission-side end face of the optical waveguide device is arranged substantially parallel to a reference line that is detected from the reference marker or a virtual reference line that is determined deliberately from a line connecting two or more reference points.

In this first configuration of a coherent light source according to the present invention, it is preferable that adjustment markers are formed on the optical waveguide device at symmetric positions in the waveguide direction with the optical waveguide at the center. With this preferable configuration, it is possible to detect the position of the optical waveguide by determining a midline between the two adjustment markers. Moreover, in this case, it is preferable that the adjustment markers are stripe-shaped markers that are formed in parallel on both sides of the optical waveguide, and the position of the optical waveguide is taken to be a midline between the two stripe-shaped markers. With this preferable configuration, the adjustment markers are always on both sides of the emission-side end face, regardless of the position of the emission-side end face of the optical waveguide device, so that the position of the optical waveguide can be detected with high precision.

In a second configuration of a coherent light source in accordance with the present invention, at least a semiconductor laser and an optical waveguide device are mounted on a submount, the submount is fixed inside a package, and when θ (<90°) is an angle between the optical waveguide on the optical waveguide device and an emission-side end face of the optical waveguide device and n is an effective refractive index of the optical waveguide, then the angle θ3 between a normal on an emission-side end face or an emission window of the package and the reference line substantially satisfies the following Equations 10 to 12:

θ1=90°−θ (Equation 10)

θ2=sin⁻¹(n×sin θ1) (Equation 11)

θ3=90°−θ2 (Equation 12)

With this second configuration of the coherent light source, control such that a beam is emitted in a direction perpendicular to the emission-side end face of the package is possible.

In this second configuration of a coherent light source according to the present invention, it is preferable that adjustment markers are formed on the optical waveguide device at symmetric positions in the waveguide direction with the optical waveguide at the center. In that case, it is further preferable that the adjustment markers are stripe-shaped markers that are formed in parallel on both sides of the optical waveguide, and the position of the optical waveguide is taken to be a midline between the two stripe-shaped markers. In that case, it is also preferable that the angle θ between the optical waveguide detected from the adjustment markers and an emission-side end face of the optical waveguide device is not greater than 87°. In that case, it is also preferable that the submount is fixed such that an intersection between the optical waveguide detected from the adjustment markers and an emission-side end face of the optical waveguide device is positioned substantially on a normal on a submount fixing face that passes through a reference point detected from the reference marker or a virtual reference point that is determined deliberately from two or more reference points. In that case, it is also preferable that the reference point is formed at a position that is left-right asymmetric with respect to an emission direction of light from the package. If the reference point is formed at a position that is left-right symmetric, then space is left over on one side of the package, and it becomes difficult to make the package more compact.

In the second configuration of a coherent light source of the present invention, it is also preferable that the optical waveguide device is a wavelength converting device utilizing second harmonic generation.

In the second configuration of a coherent light source of the present invention, it is preferable that the optical waveguide device is a wavelength converting device utilizing second harmonic generation, and the effective refractive index n is the effective refractive index for second harmonic light. This is because, of the light that is emitted from the package, the light that is utilized is the harmonic light, and the harmonic light has to be emitted perpendicularly with regard to the emission-side end face of the package.

In the first or second configuration of a coherent light source of the present invention, it is preferable that the package is made of at least one selected from the group consisting of metal, plastic and ceramic.

In the first or second configuration of a coherent light source of the present invention, it is preferable that the reference marker is a depression or a protrusion that is formed in a submount fixing face of the package.

In the first or second configuration of a coherent light source of the present invention, it is preferable that the reference marker is a reflector or an optical absorber that is formed in a submount fixing face of the package. This is because if a plastic or ceramic is used for the material of the package, then depressions or protrusions have little contrast and are hard to detect. It is possible to use a vapor deposited film of Au or the like as a reflector. Moreover, by metallizing the overall package with Au but not vapor depositing Au at the portions of the reference markers, it is possible to let it function as an optical absorber. Furthermore, it is possible to detect the reference markers with high precision in this manner.

In the first configuration of a coherent light source of the present invention, it is preferable that an emission window for outputting light is formed in an emission-side end face of the package, and the reference marker is a normal on the emission window, the normal passing through a center of the emission window. With this preferable configuration, the emission position can be adjusted with high precision with respect to the package, and also when taking the outer side of the package as a reference plane, the emission position can be controlled, which is convenient when fixing it to a device using the coherent light source. Furthermore, in this case, it is preferable that the reference marker can be detected from the emission window. When handling the submount on which the optical waveguide device has been fixed, then detection from the upper side may be blocked, but with this preferable configuration, observing through the emission window is possible, so that it is not necessary to consider the handling method, which is convenient.

In a third configuration of a coherent light source in accordance with the present invention, at least a semiconductor laser and an optical waveguide device are mounted on a submount, the submount is fixed inside a package, an emission window for outputting light is formed in an emission-side end face of the package, and the emission window is formed at a left-right asymmetric position in the emission-side end face of the package. If the emission window is formed at a left-right symmetric position, then space is left over on one side of the package, and it becomes difficult to make the package more compact.

In a fourth configuration of a coherent light source in accordance with the present invention, at least a semiconductor laser and an optical waveguide device are mounted on a submount, the submount is fixed inside a package, the optical waveguide on the optical waveguide device and a lateral face of the package are substantially parallel, an emission window for outputting light is formed in an emission-side end face of the package, the lateral face of the package and the emission window are not perpendicular to one another, and when θ(<90°) is an angle between the optical waveguide and the emission-side end face of the optical waveguide device and n is an effective refractive index of the optical waveguide, then the angle θ3 between a normal on the emission window of the package and the emission-side end face of the optical waveguide device substantially satisfies the following Equations 13 to 15:

θ1=90°−θ (Equation 13)

θ2=sin⁻¹(n×sin θ1) (Equation 14)

θ3=90°−θ2 (Equation 15)

With this fourth configuration of a coherent light source, the submount can be fixed inside the package in such a manner that the submount on which the semiconductor laser and the optical waveguide device are mounted, that is, the optical waveguide and the lateral face of the package are arranged in parallel, so that the width of the package becomes small and the package can be made compact.

In a fifth configuration of a coherent light source in accordance with the present invention, at least a semiconductor laser and an optical waveguide device are mounted on a submount, the submount is fixed inside a package, and a reference plane serving as a reference when fixing the submount is formed in a portion of the package. With this fifth configuration of a coherent light source, it is possible to realize a coherent light source, in which the emission angle and the emission position are controlled with high precision by the simple operation of butting the emission-side end face of the optical waveguide device against the reference plane.

In this fifth configuration of a coherent light source in accordance with the present invention, it is preferable that an emission-side end face of the optical waveguide device abuts against the reference plane.

In a method for manufacturing a coherent light source according to the present invention, at least a semiconductor laser and an optical waveguide device are mounted on a submount, the submount is fixed inside the package, and the submount is fixed by referencing a reference marker formed in a submount fixing face of the package or a virtual reference line or virtual reference point determined deliberately from two or more reference points.

In this method for manufacturing a coherent light source according to the present invention, it is preferable that the submount is fixed such that an emission-side end face of the optical waveguide device and a reference line detected from the reference marker are substantially parallel.

In this method for manufacturing a coherent light source according to the present invention, it is preferable that adjustment markers are formed at symmetric positions in waveguide direction with the optical waveguide on the optical waveguide device at the center, and the submount is fixed in such a manner that when θ(<90°) is an angle between the optical waveguide detected by the adjustment marker and an emission-side end face of the optical waveguide device and n is an effective refractive index of the optical waveguide, then the angle θ3 between a normal on an emission-side end face or an emission window of the package and the reference line substantially satisfies the following Equations 16 to 18:

θ1=90°−θ (Equation 16)

θ2=sin⁻¹(n×sin θ1) (Equation 17)

θ3=90°−θ2 (Equation 18)

In this case, it is preferable that after measuring the angle θ between the optical waveguide and the emission-side end face of the optical waveguide device with an image processing device that is positioned in a direction normal to the submount fixing face, θ2 is calculated using Equation 16 and Equation 17, and the angle between the reference line and the emission-side end face of the optical waveguide device is adjusted to a predetermined angle. With this preferable method, angular variations occurring when machining the emission-side end face of the optical waveguide device can be corrected.

In this case, it is also preferable that the submount is fixed such that an intersection between the optical waveguide detected from the adjustment markers and the emission-side end face of the optical waveguide device is positioned substantially on a normal on a submount fixing face that passes through a reference point detected from the reference marker or a virtual reference point that is determined deliberately from two or more reference points.

### BRIEF DESCRIPTION OF DRAWINGS

FIG. 1 diagrammatically shows the configuration of a coherent light source (without the package) in accordance with a first embodiment of the present invention,

FIG. 2 is a top view showing an optical waveguide device that is part of a coherent light source in the first embodiment of the present invention,

FIG. 3 is a cross-sectional view showing a package in the first embodiment of the present invention,

FIG. 4 is a cross-sectional view showing another example of a package in the first embodiment of the present invention (in FIG. 4A there are two virtual reference lines, and in FIG. 4B there is one virtual reference line),

FIG. 5 is a diagrammatic view illustrating a method for correcting an angular variation occurring when machining the emission-side end face of the optical waveguide in the first embodiment of the present invention,

FIG. 6 is a diagrammatic view illustrating how an emission window is provided at a left-right symmetric position of the package in the first embodiment of the present invention,

FIG. 7 diagrammatically illustrates the configuration of a coherent light source fixed to a package according to the first embodiment of the present invention,

FIG. 8A is a cross-sectional view of another example of a coherent light source fixed to a package according to the first embodiment of the present invention, and FIG. 8B is a cross-sectional view of the package,

FIG. 9A is a cross-sectional view of yet another example of a package according to the first embodiment of the present invention, and FIG. 9B is a schematic view of an image obtained by image detection,

FIG. 10 diagrammatically shows the configuration of a coherent light source in accordance with a second embodiment of the present invention,

FIG. 11 diagrammatically shows the configuration of a package of a coherent light source in a third embodiment of the present invention (FIG. 11A is a cross-sectional view and FIG. 11B is a view of the end face),

FIG. 12 diagrammatically shows the configuration of a SHG blue light source using an optical waveguide-type QPM-SHG device.

### BEST MODE FOR CARRYING OUT THE INVENTION

The following is a more detailed description of the present invention with reference to embodiments.

First Embodiment

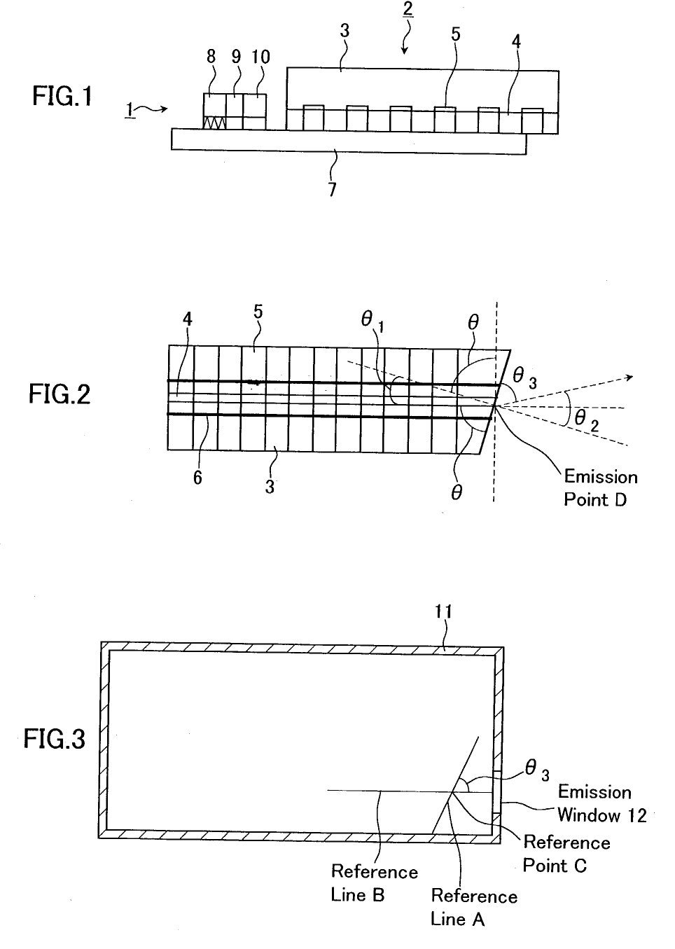

FIG. 1 diagrammatically shows the configuration of a coherent light source in accordance with a first embodiment of the present invention.

In the coherent light source of this embodiment as shown in FIG. 1, a 0.85 μm-band 100 mW-class AlGaAs wavelength-variable distributed Bragg reflection (referred to as “DBR” in the following) semiconductor laser 1 having a DBR region 8, a phase control region 9 and an active layer region 10 is used as the semiconductor laser used for the fundamental wave. In this wavelength variable DBR semiconductor laser 1, the oscillation wavelength can be changed continuously by simultaneously changing the current injected into the phase control region 9 and the DBR region 8. Moreover, a quasi phase matching (referred to as “QPM” in the following) optical waveguide-type second harmonic generation (referred to as “SHG” in the following”) device (optical waveguide-type QPM-SHG device) 2 is used as the optical waveguide device. This optical waveguide-type QPM-SHG device 2 is made of an optical waveguide 4 and periodic polarization inversion regions 5 arranged perpendicular thereto, formed on the upper surface of a 0.5 mm thick X-cut MgO-doped LiNbO₃ substrate 3. With the optical waveguide-type QPM-SHG device 2, it is possible to realize a high conversion efficiency, because it is possible to utilize its large nonlinear optical constants, and also because it is of the optical waveguide type and a long interaction length can be established. It should be noted that, as shown in FIG. 2, adjustment markers 6 are formed on the optical waveguide-type QPM-SHG device 2 at symmetrical positions along waveguide direction, with the optical waveguide 4 in the center. That is to say, the adjustment markers 6 are formed in parallel to the optical waveguide 4 on both sides of the optical waveguide 4.

As described above, the coherent light source of this embodiment is an SHG blue light source configured with a wavelength-variable DBR semiconductor laser 1 and an optical waveguide-type QPM-SHG device 2. The wavelength-variable DBR semiconductor laser 1 and the optical waveguide-type QPM-SHG device 2 are fixed on the upper surface of a Si submount 7, such that the active layer face and the optical waveguide face thereof are arranged in opposition to one another.

The following is a description of a method for fabricating an optical waveguide-type QPM-SHG device.

As mentioned above, the optical waveguide-type QPM-SHG device 2 is made of an optical waveguide 4 and periodic polarization inversion regions 5 arranged perpendicular thereto, formed on a 0.5 mm thick X-cut MgO-doped LiNbO₃ substrate 3 (see FIGS. 1 and 2). The periodic polarization inversion regions 5 are formed by forming comb-shaped electrodes on the X-cut MgO-doped LiNbO₃ substrate 3 and applying an electric field. The optical waveguide 4 is formed in a direction perpendicular to the periodic polarization inversion regions 5, and the adjustment markers 6 also are formed at the same time. That is to say, a Ta film is vapor deposited on the X-cut MgO-doped LiNbO₃ substrate 3, and the adjustment markers 6 and a stripe mask of 5 μm width for forming the optical waveguide 4 are formed simultaneously by an exposure step and a dry etching step. Then, the optical waveguide 4 is formed by performing proton exchange in pyrophosphoric acid (200° C., 7 min) and an annealing process (330° C., 200 min). After that, the adjustment markers 6 are masked by a resist, and the Ta film is removed by wet etching. Thereafter, an optical waveguide-type QPM-SHG device 2 provided with the adjustment markers 6 is fabricated by forming a SiO₂ protective film.

As shown in FIG. 2, the emission-side end face of the optical waveguide-type QPM-SHG device 2 according to this embodiment is cut obliquely. It is desirable that the angle θ between the optical waveguide 4 and the emission-side end face of the optical waveguide-type QPM-SHG device 2 is not greater than 87°, and in this embodiment, it is set to θ=84°. Thus, the amount of return light returning into the wavelength-variable DBR semiconductor laser 1 is reduced to about 1/1000. On the other hand, the coupling-side end face of the optical waveguide-type QPM-SHG device 2 is formed perpendicularly to the optical waveguide 4, so that highly efficient coupling with the wavelength-variable DBR semiconductor laser 1 can be realized. A coating that is antireflective to blue light is formed on the emission-side end face of the optical waveguide-type QPM-SHG device 2.

In this embodiment, stripe-shaped markers are used as the adjustment markers 6. That is to say, the optical waveguide 4 is formed on the midline between the two stripe-shaped markers. The stripe-shaped markers exist consistently on both sides of the emission-side end face, regardless of the position of the emission-side end face of the optical waveguide-type QPM-SHG device 2, so that their form is suitable for detecting the position of the optical waveguide 4 with high precision. The adjustment markers 6 are formed by leaving the Ta mask when forming the optical waveguide 4, so that they depend on the fabrication precision of the photo-mask when forming the Ta mask and can be formed with high precision. For this reason, the adjustment markers 6 and the optical waveguide 4 are parallel, and it is possible to measure the angle θ between the optical waveguide 4 and the emission-side end face of the optical waveguide-type QPM-SHG device 2 by measuring the angle between the adjustment markers 6 and the emission-side end face of the optical waveguide-type QPM-SHG device 2. In this embodiment, θ was 84.2°.

From the measured angle θ between the optical waveguide 4 and the emission-side end face of the optical waveguide-type QPM-SHG device 2, the mounting angle for mounting in the package is determined, and the Si submount 7 on which the wavelength-variable DBR semiconductor laser 1 and the optical waveguide-type QPM-SHG device 2 have been mounted is fixed in the package.

FIG. 3 shows a cross-sectional view of a package used for the present embodiment.

As shown in FIG. 3, a reference marker (reference line A) is formed on the Si submount fixing face of the package 11. The reference line A corresponds to the setting angle θ=84° between the optical waveguide 4 and the emission-side end face of the optical waveguide-type QPM-SHG device 2. In the proton exchange optical waveguide 4 on the X-cut MgO-doped LiNbO₃ substrate 3, the effective refractive index n for harmonic light (blue light) is 2.32. Here, the reason why the effective refractive index for harmonic light (blue light) is used is because the harmonic light of the light that is emitted from the package 11 is the light that is utilized, and the harmonic light has to be emitted perpendicularly with regard to the emission-side end face of the package 11, that is, the emission window. For this reason, when the angle between the optical waveguide 4 and the emission-side end face of the optical waveguide-type QPM-SHG device 2 in FIG. 2 is θ=84° (<90°), then the blue light is emitted from the end face in a direction θ2 that satisfies the following Equations 19 and 20:

θ1=90°−θ (Equation 19)

θ2=sin⁻¹(n×sin θ1) (Equation 20)

Moreover, the angle θ3 between the reference line A and the normal on the emission-side end face of the package 11 is defined by the following Equation 21. It should be noted that in this embodiment, the emission-side end face of the package and the emission window through which the light is output are parallel.

θ3=90°−θ2 (Equation 21)

Inserting specific numbers into Equations 19 to 21, the angle θ3 between the reference line A and the normal on the emission-side end face of the package 11 can be calculated to be 75.97°.

As shown in FIG. 3, an emission window 12 for outputting light is provided on the emission-side end face of the package 11. Reference markers (reference line A and reference line B) are formed on the Si submount fixing face of the package 11. Here, the reference line B is a normal to the emission window 12.

The optical waveguide-type QPM-SHG device 2 is adjusted using an image processing device that is positioned in a direction normal to the face on which the SHG blue light source is mounted to the package 11, such that the emission-side end face of the optical waveguide-type QPM-SHG device 2 and the reference line A of the package 11 are parallel. Furthermore, the emission point D (see FIG. 2) of the SHG blue light source is adjusted to the desired position. As shown in FIG. 2, in this embodiment, the optical waveguide 4 is positioned on the midline between the two stripe-shaped markers (adjustment markers 6), so that the intersection between this midline and the emission-side end face of the optical waveguide-type QPM-SHG device 2 becomes the emission point D. Furthermore, the intersection between the reference line A and the reference line B serves as a reference point C for adjusting the emission point D, and this reference point C is set to a position that is left-right asymmetric with respect to the emission direction of light from the package 11. The emission point D and the reference point C are adjusted with an image processing device such that they both coincide, and then, the Si submount 7 of the SHG blue light source is fixed to the package 11 using an adhesive. That is to say, the Si submount 7 is fixed such that the intersection (emission point D) between the optical waveguide 4 detected with the adjustment markers 6 and the emission-side end face of the optical waveguide-type QPM-SHG device 2 is located on the normal on the Si submount fixing face, which passes through the intersection (reference point C) between the reference line A and the reference line B.

It should be noted that in this embodiment, the reference point C for adjusting the emission point D is taken to be the intersection between the reference line A and the reference line B, but the reference point C for adjusting the emission point D can be determined even without forming the reference line A and the reference line B if two or more reference markers (reference points) are formed, by taking virtual lines connecting the reference markers as the reference line A and the reference line B. In this case, it is also possible to actually form the reference point C.

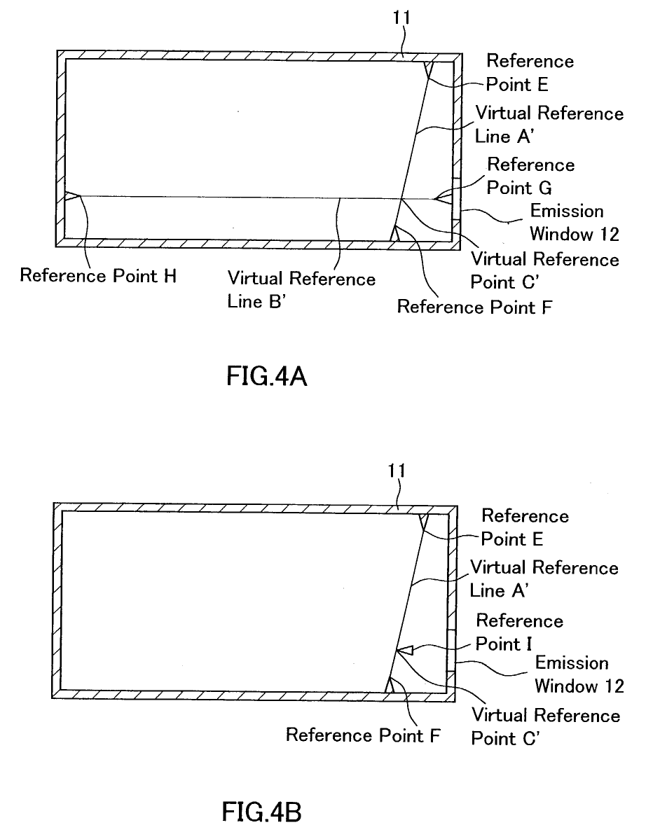

A configuration and method for determining virtual reference lines A′ and B′ when two or more reference markers are actually formed is described with reference to FIG. 4.

In the package 11 shown in FIG. 4A, a virtual reference line A′ that is obtained from two reference markers (reference point E and reference point F) and a virtual reference line B′ that is obtained from two reference markers (reference point G and reference point H) are used as virtual reference lines that are determined deliberately from lines connecting the two or more reference points. Furthermore, the virtual reference point C′ is obtained from the virtual reference line A′ and the virtual reference line B′. Moreover, by adjusting the virtual reference line A′ and the emission-side end face of the optical waveguide-type QPM-SHG device 2 (see FIG. 2) such that they are parallel, and moreover such that the emission point D (see FIG. 2) and the virtual reference point C′ coincide, the emission point D and the emission direction of the harmonic light emitted from the optical waveguide-type QPM-SHG device 2 can be adjusted with high precision with respect to the package 11.

The reference markers shown in FIG. 4A are triangular protrusions that are formed on the lateral faces of the package 11. In that case, it is possible to take the tips of the triangles as reference points, so that the virtual reference lines can be obtained with high precision. Furthermore, in this case it is possible to detect the reference line A′ even after the Si submount 7 of the SHG blue light source (see FIG. 1) has been fixed to the package 11, so that it is easy to perform inspections after fixing the Si submount.

In the package 11 shown in FIG. 4B, the virtual reference line A′ obtained from two reference markers (reference point E and reference point F) is used as a virtual reference line that is determined deliberately from a line connecting two or more reference points. Furthermore, a virtual reference point C′ is obtained from a reference point I that is formed on the Si submount fixing face of the package 11. Then, by adjusting the virtual reference line A′ and the emission-side end face of the optical waveguide-type QPM-SHG device 2 (see FIG. 2) such that they are parallel, and moreover such that the emission point D (see FIG. 2) coincides with the virtual reference point C′, the emission point D and the emission direction of the harmonic light emitted from the optical waveguide-type QPM-SHG device 2 can be adjusted with high precision with respect to the package 11.

Metal, plastic, ceramic or the like can be used as the material for the package 11.

Moreover, the reference markers, such as the reference lines A and B, can be formed for example by machining depressions or protrusions into the Si submount fixing face of the package 11. It is also possible to use a reflector or an optical absorber for the reference markers. This is because if plastic or ceramic is used as the material of the package 11, then depressions or protrusions have little contrast and are hard to detect. It is possible to use a vapor deposited film of Au or the like as the reflector. Moreover, by metallizing the overall package with Au but not vapor depositing Au at the portions of the reference markers, it is possible to let it function as an optical absorber. Furthermore, it is possible to detect the reference markers with high precision in this manner.

In the present embodiment, if the adjustment markers 6 are formed by leaving the Ta mask when forming the optical waveguide 4, then the adjustment markers 6 are formed with high precision with respect to the optical waveguide 4, so that the position of the emission point D also can be detected with high precision. As a result, it is possible to adjust not only the emission angle but also the position of the emission point D with high precision when fixing the Si submount 7 of the SHG blue light source to the package 11.

It should be noted that in the present embodiment, stripe-shaped markers were used for the adjustment markers 6, but it is also possible to attain a similar effect with square, circular or cross-shaped markers, as long as they are arranged symmetrically with the optical waveguide 4 in the center.

In accordance with the present invention, by letting the emission point D coincide with the reference point C (or the virtual reference point C′), it is possible to make the position of the emission point of the SHG blue light source constant with respect to the package 11. When applied to an optical disk apparatus or the like, it is possible to simplify the positional adjustment of the optical system with the collimate lens and the like, so that the merits are considerable.

In the optical waveguide-type QPM-SHG device 2 used for the present embodiment, the actual angle θ between the optical waveguide 4 and the emission-side end face of the optical waveguide-type QPM-SHG device 2 was 84.2° for a set angle of 84°. For this reason, the emission angle θ2 was 13.56°. Thus, blue light was emitted at an angle of 0.47° with respect to the emission window 12 (or the emission-side end face) of the package 11. This value satisfies an emission direction tolerance of about ±1°, which is required for optical disk apparatuses or the like.

However, the angle θ between the optical waveguide 4 and the emission-side end face of the optical waveguide-type QPM-SHG device 2 sometimes varies due to the machining process. The following is a description of an adjustment method and a mounting method for that case.

First of all, using an image processing device positioned in a direction normal to the mounting face of the package 11 on which the SHG blue light source is mounted, the angle θ between the optical waveguide 4 and the emission-side end face of the optical waveguide-type QPM-SHG device 2 is measured. Next, using the above-noted Equations 19 and 20, the emission angle θ2 is calculated. If the angle θ between the optical waveguide 4 and the emission-side end face of the optical waveguide-type QPM-SHG device 2 is 85°, then the emission angle θ2 is 11.67°. Consequently, by adjusting the angle θ4 between the reference line A and the emission-side end face of the optical waveguide-type QPM-SHG device 2 so that it is 2.36° (see FIG. 5), the angular variation when machining the emission-side end face of the optical waveguide-type QPM-SHG device 2 can be corrected. After correcting the angular variation that occurred when machining the emission-side end face of the optical waveguide-type QPM-SHG device 2, the emission point D of the optical waveguide 4 and the reference point C of the package 11 were adjusted such that the two coincide, using the image processing device, and the Si submount 7 of the SHG blue light source was fixed to the package 11 using an adhesive. Thus, variations in the emission angle θ2 could be reduced to a minimum.

In the present embodiment, by setting the angle between the optical waveguide 4 and the emission-side end face of the optical waveguide-type QPM-SHG device 2 to 84°, the amount of return light could reduced to 1/500, and with an anti-reflection (AR) coating with a reflectivity of 0.5% on the emission-side end face, the amount of return light could be reduced to 0.001%. Therefore, it was possible to realize stable wavelength variability and a reduction in optical noise.

The following factors can be listed as reasons for a tilting of the emission direction with respect to the submount when a coherent light source, in which a semiconductor laser and an optical waveguide device have been mounted on the submount, is fixed in a package:

(1) the mounting angle of the semiconductor laser;

(2) the machining precision of the coupling-side end face of the optical waveguide device; and

(3) the oblique angle of the emission-side end face of the optical waveguide device and its machining precision.

The factors (1) and (2) can be addressed by adjusting the emission-side end face and the reference lines of the package as in the present embodiment, so that the practical effect of the present invention is considerable. Furthermore, the factor (3) can be addressed as well by measuring the angle between the optical waveguide and the emission-side end face and performing a correction with respect to the reference line, so that the practical effect of the present invention is considerable.

When taking the submount as a reference and fixing the coherent light source to the package, the emission point and the emission angle may vary with respect to the package, due to the above-listed factors (1) to (3). By forming reference lines or reference points on the package as in the present embodiment and forming high-precision adjustment markers also on the optical waveguide-type QPM-SHG device, it is possible to adjust the emission point and the emission angle with respect to the package. Moreover, by decreasing variations of the emission point and the emission angle with respect to the package, it is possible to decrease variations in the light utilization efficiency when applying the coherent light source to an optical disk apparatuses or the like, which makes it possible to decrease the optical output that is necessary in consideration of yield or the like, so that the practical effect is considerable.

Ordinarily, the phenomenon that noise is increased due to return light from the outside occurs in semiconductor lasers. Moreover, optical disk apparatuses or the like require coherent light sources with little noise. In SHG light sources that are made of a semiconductor laser and an optical waveguide device (wavelength converting device), wavelength-converted harmonic light is used, so that return light from the outside does not lead to an increase of noise in the semiconductor laser. However, when there is return light from the wavelength converting device, then a similar phenomenon of increased noise occurs. As disclosed in JP 2000-171653A, the return light from the emission-side end face of an optical waveguide-type wavelength converting device can be reduced by obliquely cutting the emission-side end face of the optical waveguide-type wavelength converting device. A configuration in which the emission-side end face of the wavelength converting device is cut obliquely is advantageous in particular in wavelength converting devices utilizing second harmonic generation (SHG), and thus it is possible to realize a short-wavelength light source with low noise. By mounting an SHG light source made of a semiconductor laser and an optical waveguide-type wavelength converting device with an obliquely cut emission-side end face on a package on which reference lines and reference points are formed as in the present embodiment, it is possible to reduce variations regarding the emission point or the emission angle with respect to the package, so that the practical effect is considerable.

In the present embodiment, the angle between the optical waveguide and the emission-side end face of the optical waveguide device was 84°. Thus, stable wavelength conversion characteristics and generation of harmonics with little noise can be realized. With current technology, an AR coating with a reflectivity of about 0.1% is possible. If the angle between the optical waveguide and the emission-side end face is 86°, then the effect of reducing the return light is about 1/100. Thus, as in the present embodiment, the return light can be reduced to 0.001%, so that stable wavelength conversion characteristics and generation of harmonics with little noise can be realized.

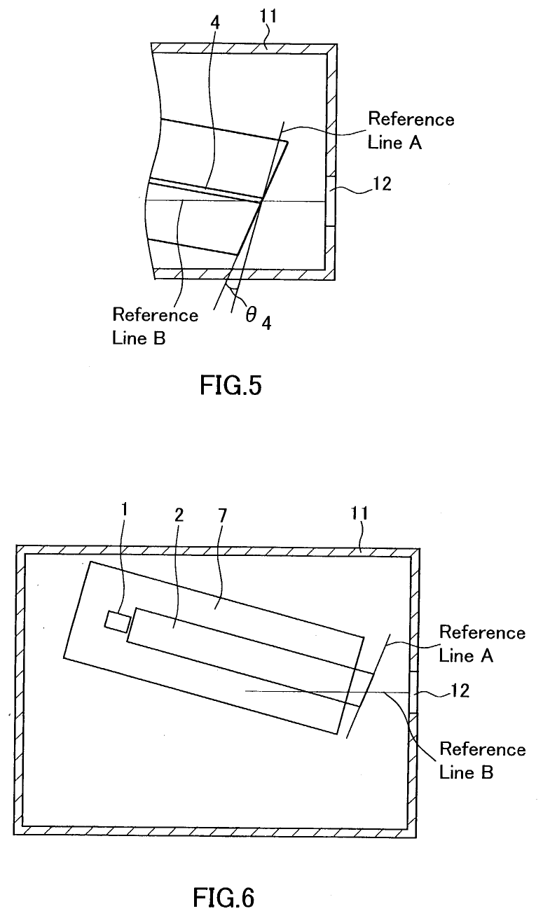

The package of the present embodiment is characterized in that the emission window is not positioned centrosymmetrically (left-right symmetrically) with respect to the emission-side end face of the package, and also the reference line B is not positioned centrosymmetrically (left-right symmetrically). As shown in FIG. 6, if the reference line B is arranged at a centrosymmetric position, then space is left unused on one side of the package 11 (lower half in FIG. 6), and it becomes difficult to make the package 11 more compact. Consequently, as a package for SHG light sources configured using an optical waveguide device whose emission-side end face has been cut obliquely, it is advantageous in practice to provide a emission window 12 with a structure that is left-right asymmetric, as in the present embodiment.

If the coherent light source is applied to an optical information processing apparatus, such as an optical disk apparatus, then it is necessary that the emission direction of the light is perpendicular to the emission-side end face of the package, that is, perpendicular to the emission window. The reason for that is that when a transparent plate is inserted obliquely into the path of divergent light, then astigmatism occurs when the light is focused.

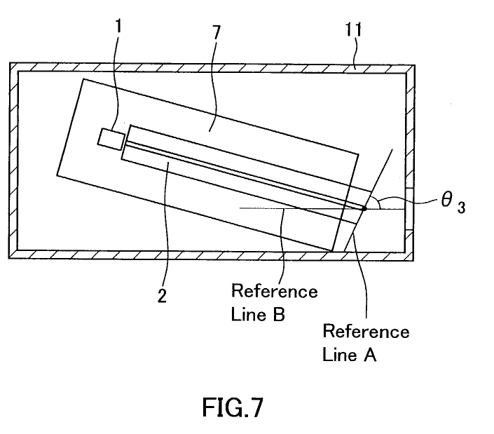

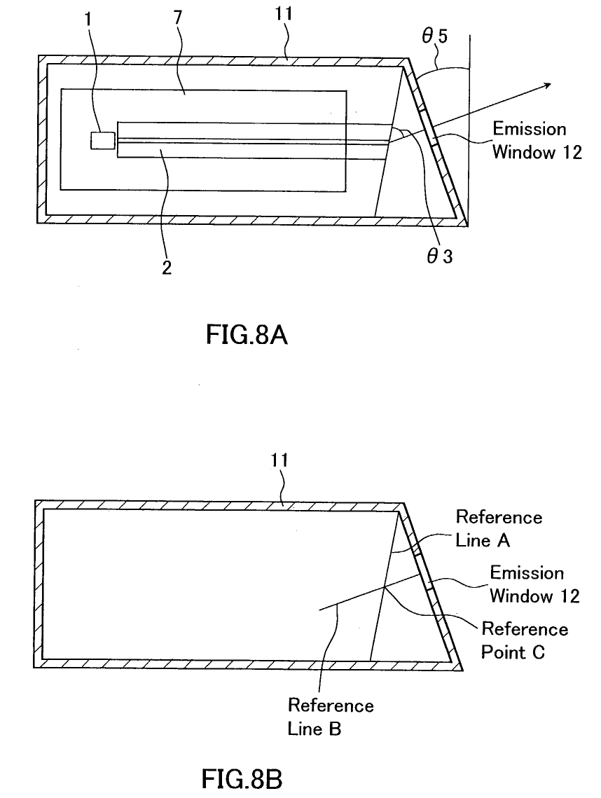

In the coherent light source shown in FIG. 7, the emission window 12 is perpendicular to the lateral side of the package 11, and the emitted light is obtained in a direction that is parallel to the package 11. However, by arranging the emission-side end face or the emission window 12 of the package 11 obliquely (by configuring the lateral face of the package 11 and the emission-side end face or the emission window 12 of the package 11 such that they are not perpendicular to one another), an even more compact configuration is possible. FIG. 8 shows this configuration. The emission direction of the blue light is described with reference to FIG. 2.

When the angle between the optical waveguide 4 and the emission-side end face of the optical waveguide-type QPM-SHG device 2 in FIG. 2 is θ=84° (<90°), then the blue light is emitted from the end face in a direction θ2 that satisfies the following Equations 22 and 23:

θ1=90°−θ (Equation 22)

θ2=sin⁻¹(n×sin θ1) (Equation 23)

Moreover, the angle θ3 between the reference line A and the normal on the emission-side end face or the emission window 12 of the package 11 is defined by the following Equation 24.

θ3=90°−θ2 (Equation 24)

When inserting specific numbers into Equations 22 to 24, the angle θ3 between the reference line A and the normal on the emission-side end face of the package 11 can be calculated to be 75.97°.

As shown in FIG. 8, the emission-side end face of the package 11 is provided with an emission window 12 for outputting light, and the tilt angle θ5 of the emission-side end face (emission window 12) of the package 11 is defined by the following Equation 25.

θ5=90°−θ3−θ1 (Equation 25)

Since in the present embodiment ƒ1 is 6°, θ3 becomes 75.97°, and in accordance with Equation 25, θ5 becomes 8.03°.

If the package configuration shown in FIG. 8 is used, then the Si submount 7 on which the wavelength-variable DBR semiconductor laser 1 and the optical waveguide-type QPM-SHG device 2 are mounted can be fixed inside the package 11 in such a manner that the the Si submount 7, that is, the optical waveguide, and the lateral sides of the package 11 are parallel. Thus the width of the package 11 can be made small, making the package 11 more compact.

It should be noted that with the configuration shown in FIG. 8, the emission-side end face of the package 11 is parallel to the emission window 12 for outputting light, but a similar effect also can be attained when the cross-sectional shape of the package 11 is rectangular. In that case, the angle between the reference line A and the normal on the emission window 12 should be designed such that it is θ3.

Also in the configuration shown in FIG. 8, by adjusting the reference line A and the emission-side end face of the optical waveguide-type QPM-SHG device 2 such that they are parallel, and moreover such that the reference point C coincides with the emission point D (see FIG. 2), the emission point D and the emission angle of the light with respect to the package 11 can be adjusted with high precision. Consequently, when mounted on an optical information processing apparatus, such as an optical disk apparatus, it is possible to reduce variations in the optical utilization efficiency, so that the optical output that is necessary in consideration of the yield or the like can be reduced, and thus its practical effect is considerable.

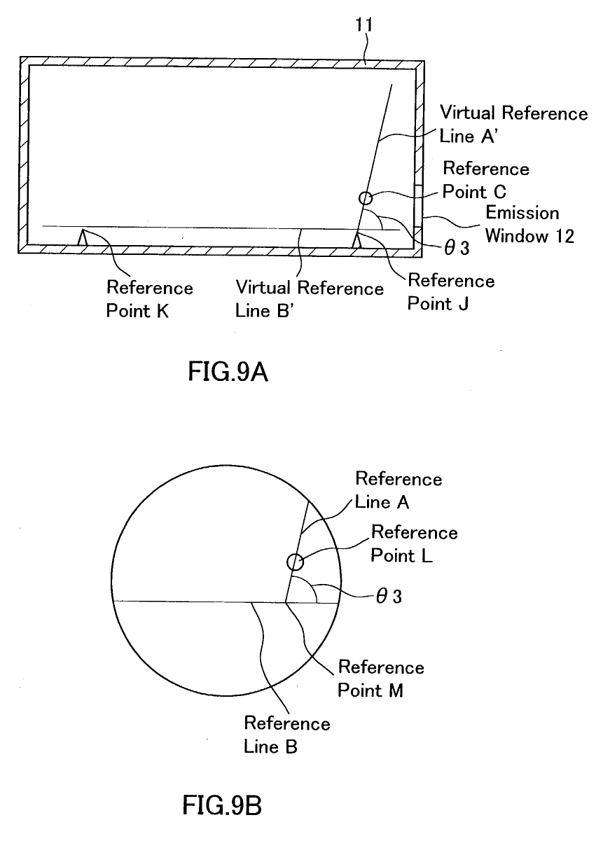

Furthermore, in the coherent light source shown in FIG. 9, the virtual reference line A′ and the virtual reference line B′, which connect reference points that are formed inside the package 11, are determined, and taking them as a reference, the Si submount 7 on which the wavelength-variable DBR semiconductor laser 1 and the optical waveguide-type QPM-SHG device 2 are mounted can be adjusted and fixed. In that case, also when setting, as the virtual reference lines that are determined deliberately from lines that connect two or more reference points, reference lines that are obtained within a detection image taking certain reference points as a reference, it is possible to control the emission angle and the emission position with high precision.

FIG. 9A diagrammatically shows the configuration of a package in which reference points are formed on a lateral face of the package. As shown in FIG. 9A, a virtual reference line B′ is obtained from a reference point J and a reference point K. FIG. 9B shows the image obtained by image detection. As shown in FIG. 9B, the reference line A, the reference B and the reference point L are formed in advance in the image (the intersection between the reference line A and the reference line B is taken as the reference point M).

Since the reference line A and the reference line B have been formed in advance at an angle θ3 in the detection image, it is possible to deliberately determine the virtual reference line A′ if the package 11 is adjusted such that the virtual reference B′ coincides with the reference line B and the reference point J coincides with the reference point M. If the Si submount is adjusted such that the emission-side end face of the optical waveguide-type QPM-SHG device coincides with the reference line A, and moreover the emission point D (see FIG. 2) coincides with the reference point C, then the emission point D and the emission angle can be controlled with respect to the emission window 12 (emission-side end face) of the package 11.

Also in this case, as in the case of the configuration shown in FIG. 8, when mounted on an optical information processing apparatus, such as an optical disk apparatus, it is possible to reduce variations in the optical utilization efficiency, so that the optical output that is necessary in consideration of the yield or the like can be reduced, and thus the practical effect is considerable.

Second Embodiment

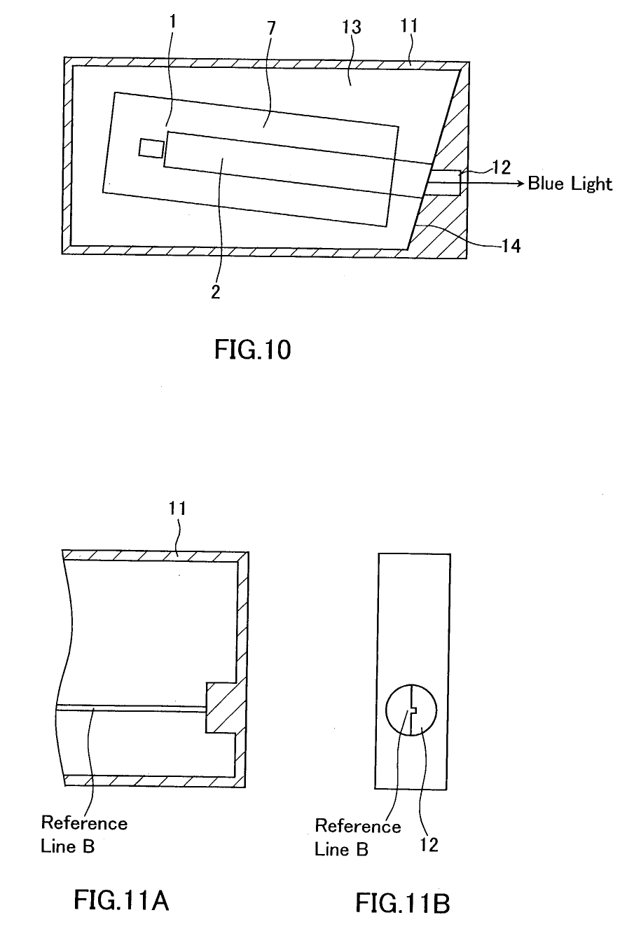

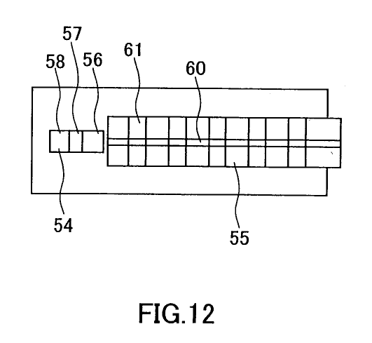

FIG. 10 diagrammatically shows the configuration of a coherent light source in accordance with a second embodiment of the present invention.

In the coherent light source of this embodiment as shown in FIG. 10, as in the first embodiment, a SHG blue light source is configured with a wavelength-variable DBR semiconductor laser 1 and an optical waveguide-type QPM-SHG device 2, and the wavelength-variable DBR semiconductor laser 1 and the optical waveguide-type QPM-SHG device 2 are fixed on the upper surface of a Si submount 7 such that the active layer face and the optical waveguide face thereof are arranged in opposition to one another. Furthermore, as in the above-described first embodiment, the emission-side end face of the optical waveguide-type QPM-SHG device 2 is cut obliquely.

The package 11 is provided with a reference plane 14 by forming an inner end face, which is perpendicular to the Si submount fixing face 13, such that it is oblique with respect to the longitudinal direction of the package 11. The reference plane 14 is arranged such that it is parallel to the reference line A in the first embodiment. Then, when fixing the Si submount 7, on which the wavelength-variable DBR semiconductor laser 1 and the optical waveguide-type QPM-SHG device 2 have been mounted, to the Si submount fixing face 13 inside the package 11, the optical waveguide-type QPM-SHG device 2 can be fixed at the desired position within the package 11 by abutting the obliquely cut emission-side end face of the optical waveguide-type QPM-SHG device 2 against the reference plane 14.

With this embodiment, positioning is carried out without image adjustment by the simple operation of butting the emission-side end face of the optical waveguide-type QPM-SHG device 2 against the reference plane 14, so that the time that is necessary for mounting can be reduced.

It should be noted that other configurational aspects, such as the reference line B are similar to the first embodiment, so that their further description has been omitted.

Third Embodiment

FIG. 11 diagrammatically shows the configuration of the package of a coherent light source in accordance with a third embodiment of the present invention (FIG. 11A is a cross-sectional view and FIG. 11B is a view of the end face).

As shown in FIG. 11, the package 11 of the coherent light source of this embodiment is provided with an emission window 12 for outputting light at a position that is left-right asymmetric of the emission-side end face of the package 11. Moreover, the Si submount fixing face of the package 11 is provided with a reference marker (reference line B) by forming a groove. This reference line B is normal to the emission window 12 and passes through the center of the emission window 12. When handling the Si submount on which the optical waveguide-type QPM-SHG device has been fixed, detection from the upper side may be blocked, but providing a reference line B of the above-describe shape, the reference line B can be detected from the emission window 12, so that it is not necessary to consider the handling method, which is convenient.

It should be noted that other configurational aspects, such as the reference line A are similar to the first embodiment, so that their further description has been omitted.

### INDUSTRIAL APPLICABILITY

As described above, with the present invention, a coherent light source can be realized, in which the emission angle and the emission position are controlled with high precision.

1. A coherent light source in which at least a semiconductor laser and an optical waveguide device are mounted on a submount, and the submount is fixed inside a package,
wherein a reference marker serving as a reference when fixing the submount is formed on a submount fixing face of the package.

2. The coherent light source according to claim 1, wherein the submount is fixed in such a manner that an emission-side end face of the optical waveguide device is arranged substantially parallel to a reference line that is detected from the reference marker or a virtual reference line that is determined deliberately from a line connecting two or more reference points.

3. The coherent light source according to claim 1 or 2, wherein adjustment markers are formed on the optical waveguide device at symmetric positions in the waveguide direction with the optical waveguide at the center.

4. The coherent light source according to claim 3, wherein the adjustment markers are stripe-shaped markers that are formed in parallel on both sides of the optical waveguide, and the position of the optical waveguide is taken to be a midline between the two stripe-shaped markers.

5. A coherent light source in which at least a semiconductor laser and an optical waveguide device are mounted on a submount, and the submount is fixed inside a package,
wherein when θ (<90°) is an angle between the optical waveguide on the optical waveguide device and an emission-side end face of the optical waveguide device and n is an effective refractive index of the optical waveguide, then the angle θ3 between a normal on an emission-side end face or an emission window of the package and the reference line substantially satisfies the following Equations 1 to 3:
θ1=90°−θ (Equation 1)
θ2=sin⁻¹(n×sin θ1) (Equation 2)
θ3=90°−θ2 (Equation 3)

6. The coherent light source according to claim 5, wherein adjustment markers are formed on the optical waveguide device at symmetric positions in the waveguide direction with the optical waveguide at the center.

7. The coherent light source according to claim 6, wherein the adjustment markers are stripe-shaped markers that are formed in parallel on both sides of the optical waveguide, and the position of the optical waveguide is taken to be a midline between the two stripe-shaped markers.

8. The coherent light source according to claim 6, wherein an angle between the optical waveguide detected from the adjustment markers and an emission-side end face of the optical waveguide device is not greater than 87°.

9. The coherent light source according to claim 6, wherein the submount is fixed such that an intersection between the optical waveguide detected from the adjustment markers and an emission-side end face of the optical waveguide device is positioned substantially on a normal to a submount mounting face that passes through a reference point detected from the reference marker or a virtual reference point that is determined deliberately from two or more reference points.

10. The coherent light source according to claim 9, wherein the reference point is formed at a position that is left-right asymmetric with respect to an emission direction of light from the package.

11. The coherent light source according to claim 5, wherein the optical waveguide device is a wavelength converting device utilizing second harmonic generation.

12. The coherent light source according to claim 5, wherein the optical waveguide device is a wavelength converting device utilizing second harmonic generation, and the effective refractive index n is the effective refractive index for second harmonic light.

13. The coherent light source according to any of claims 1 to 12, wherein the package is made of at least one selected from the group consisting of metal, plastic and ceramic.

14. The coherent light source according to any of claims 1 to 12, wherein the reference marker is a depression or a protrusion that is formed in a submount fixing face of the package.

15. The coherent light source according to any of claims 1 to 12, wherein the reference marker is a reflector or an optical absorber that is formed in a submount fixing face of the package.

16. The coherent light source according to claim 1, wherein an emission window for outputting light is formed in an emission-side end face of the package, and the reference marker is a normal on the emission window, the normal passing through a center of the emission window.

17. The coherent light source according to claim 16, wherein the reference marker can be detected from the emission window.

18. A coherent light source in which at least a semiconductor laser and an optical waveguide device are mounted on a submount, and the submount is fixed inside a package,
wherein an emission window for outputting light is formed in an emission-side end face of the package, and the emission window is formed at a left-right asymmetric position in the emission-side end face of the package.

19. A coherent light source in which at least a semiconductor laser and an optical waveguide device are mounted on a submount, and the submount is fixed inside a package,
wherein the optical waveguide on the optical waveguide device and a lateral face of the package are substantially parallel, wherein an emission window for outputting light is formed in an emission-side end face of the package, the lateral face of the package and the emission window are not perpendicular to one another, and when θ (<90°) is an angle between the optical waveguide and the emission-side end face of the optical waveguide device and n is an effective refractive index of the optical waveguide, then the angle θ3 between a normal on the emission window of the package and the emission-side end face of the optical waveguide device substantially satisfies the following Equations 4 to 6:
θ1=90°−θ (Equation 4)
θ2=sin⁻¹(n×sin θ1) (Equation 5)
θ3=90°θ2 (Equation 6)

20. A coherent light source in which at least a semiconductor laser and an optical waveguide device are mounted on a submount, and the submount is fixed inside a package, wherein a reference plane serving as a reference when fixing the submount is formed in a portion of the package.

21. The coherent light source according to claim 20, wherein an emission-side end face of the optical waveguide device abuts against the reference plane.

22. A method for manufacturing a coherent light source in which at least a semiconductor laser and an optical waveguide device are mounted on a submount, and the submount is fixed inside the package, wherein the submount is fixed by referencing a reference marker formed in a submount fixing face of the package or a virtual reference line or virtual reference point determined deliberately from two or more reference points.

23. The method for manufacturing a coherent light source according to claim 22, wherein the submount is fixed such that an emission-side end face of the optical waveguide device and a reference line detected from the reference marker are substantially parallel.

24. The method for manufacturing a coherent light source according to claim 22, wherein adjustment markers are formed at symmetric positions in waveguide direction with the optical waveguide on the optical waveguide device at the center, and wherein the submount is fixed in such a manner that when θ (<90°) is an angle between the optical waveguide detected by the adjustment marker and an emission-side end face of the optical waveguide device and n is an effective refractive index of the optical waveguide, then the angle θ3 between a normal on an emission-side end face or an emission window of the package and the reference line substantially satisfies the following Equations 7 to 9:
θ1=90°−θ (Equation 7)
θ2=sin⁻¹(n×sin θ1) (Equation 8)
θ3=90°−θ2 (Equation 9)

25. The method for manufacturing a coherent light source according to claim 24, wherein after measuring the angle θ between the optical waveguide and the emission-side end face of the optical waveguide device with an image processing device that is positioned in a direction normal to the submount fixing face, θ2 is calculated using Equation 7 and Equation 8, and the angle between the reference line and the emission-side end face of the optical waveguide device is adjusted to a predetermined angle.

26. The method for manufacturing a coherent light source according to claim 24 or 25, wherein the submount is fixed such that an intersection between the optical waveguide detected from the adjustment markers and the emission-side end face of the optical waveguide is positioned substantially on a normal on a submount mounting face that passes through a reference point detected from the reference marker or a virtual reference point that is determined deliberately from two or more reference points.
